(19) United States
(12) Patent Application Publication
(10) Pub. No.: US 2004/0192057 A1
(43) Pub. Date: Sep. 30, 2004

(54) Technique for forming an oxide/nitride layer stack by compensating nitrogen non-uniformities

(76) Inventors: Karsten Wieczorek, Dresden (DE); Falk Graetsch, Dresden (DE); Lutz Herrmann, Dresden (DE)

Correspondence Address: J. Mike Amerson, Williams, Morgan & Amerson, P.C., Suite 1100, 10333 Richmond, Houston, TX, 77042, US

(21) Appl. No.: 10/693,024

(22) Filed: Oct. 24, 2003

(30) Foreign Application Priority Data
Mar. 31, 2003 (DE) 103 14 504.4

(51) Int. Cl. H01L 21/302; H01L 21/461

(52) U.S. Cl. 438/706

(57) ABSTRACT

The present invention provides a technique for forming extremely thin insulation layers requiring the incorporation of specified amounts of nitrogen, wherein the effect of nitrogen variations across the substrate surface may be reduced in that during and/or after the nitrogen incorporation an oxidation process is performed. The nitrogen variations lead to a nitrogen concentration dependent oxidation rate and, hence, a nitrogen concentration dependent thickness variation of the insulating layer. In particular, the threshold variations of transistors including the thin insulating layer as a gate insulation layer may effectively be reduced.

### BACKGROUND OF THE INVENTION

1. Field of the Invention

Generally, the present invention relates to the field of fabricating microstructures such as integrated circuits, micromechanical structures and the like, and, more particularly, to the formation of an ultra-thin dielectric oxide layer having incorporated therein nitrogen to increase the permittivity thereof and to reduce charge carrier migration through the oxide layer.

2. Description of the Related Art

Presently, microstructures are integrated into a wide variety of products. One example in this respect is the employment of integrated circuits that, due to their relatively low cost and high performance, are increasingly used in many types of devices, thereby allowing superior control and operation of those devices. Due to economic reasons, manufacturers of microstructures, such as integrated circuits, are confronted with the task of steadily improving performance of these microstructures with every new generation appearing on the market. However, these economic constraints not only require improving the device performance but also demand a reduction in size so as to provide more functionality of the integrated circuit per unit chip area. Thus, in the semiconductor industry, ongoing efforts are being made to reduce the feature sizes of feature elements. In present-day technologies, the critical dimension of these elements approach 0.1 μm and less. In producing circuit elements of this order of magnitude, process engineers are confronted with many challenges, along with many other issues especially arising from the reduction of feature sizes. For example, one such issue involves providing extremely thin dielectric layers on an underlying material layer, wherein certain characteristics of the dielectric layer, such as permittivity and/or resistance against charge carrier tunneling and the like, have to be improved without sacrificing the physical properties of the underlying material layer.

One important example in this respect is the formation of ultra-thin gate insulation layers of field effect transistors, such as MOS transistors. The gate dielectric of a transistor has an essential impact on the performance of the transistor. As is commonly known, reducing the size of a field effect transistor, that is reducing the length of a conductive channel that forms in a portion of a semiconductor region by applying a control voltage to a gate electrode formed on the gate insulation layer, also requires the reduction of the thickness of the gate insulation layer to maintain the required capacitive coupling from the gate electrode to the channel region.

Currently, most of the highly sophisticated integrated circuits, such as CPUs, memory chips and the like, are based on silicon and, therefore,. silicon dioxide has preferably been used as the material for the gate insulation layer due to the well known and superior characteristics of the silicon dioxide/silicon interface. For a channel length on the order of 100 nm and less, however, the thickness of the gate insulation layer has to be reduced to about 2 nm in order to maintain the required controllability of the transistor operation. Steadily decreasing the thickness of the silicon dioxide gate insulation layer, however, leads to an increased leakage current therethrough, thereby resulting in an unacceptable increase of static power consumption as the leakage current exponentially increases for a linear reduction of the layer thickness.

Therefore, great efforts are presently being made to replace silicon dioxide by a dielectric exhibiting a higher permittivity so that a thickness thereof may be higher than the thickness of a corresponding silicon dioxide layer providing the same capacitive coupling. A thickness for obtaining a specified capacitive coupling will also be referred to as capacitive equivalent thickness and determines the thickness that would be required for a silicon dioxide layer. It turns out, however, that it is difficult to incorporate high-k materials into the conventional integration process and, more importantly, the provision of a high-k material as a gate insulation layer seems to have a significant influence on the carrier mobility in the underlying channel region, thereby remarkably reducing the carrier mobility and thus the drive current capability. Hence, although an improvement of the static transistor characteristics may be obtained by providing a thick high-k material, at the same time an unacceptable degradation of the dynamic behavior presently makes this approach less than desirable.

A similar approach that is currently favored is the employment of an integrated silicon oxide/nitride layer stack that may reduce the gate leakage current by 0.5 to 2 orders of magnitude while maintaining compatibility with standard CMOS process techniques. It has been found that the reduction of the gate leakage current mainly depends upon the nitrogen concentration incorporated into the silicon dioxide layer by means of plasma nitridation.

A different approach has been suggested to overcome the problem of insufficient capacitive coupling of the gate electrode to the channel region. As is commonly known, the gate electrode is typically made of polysilicon with a high amount of dopants introduced to increase the conductivity of the polysilicon. A depletion layer may, however, form in the gate electrode in the vicinity of the gate insulation layer, the extension of which depends on the degree of doping in the depleted region. The depletion layer not only reduces the overall conductivity but also decreases the capacitive coupling. Therefore, in an attempt to extenuate these disadvantages, a high dopant concentration reaching as closely as possible to the gate insulation layer has been proposed in the polysilicon gate electrode. The incorporation of a high amount of dopants, especially of boron that readily diffuses, renders this approach less than desirable, as particularly P-channel transistors suffer from a deteriorated gate reliability in combination with a reduced channel mobility and an offset in the threshold voltage caused by boron ions penetrating the gate insulation layer and the underlying channel region.

For these reasons, the incorporation of nitrogen into silicon dioxide based gate insulation layers is currently considered an attractive approach, although a plurality of issues are associated with the reliable and reproducible introduction of nitrogen into a thin silicon dioxide layer across the entire substrate surface as will be described in more detail with reference to FIGS. 1a-1d.

FIG. 1a schematically shows a cross-sectional view of a semiconductor device 100 including a substrate 101, for example a silicon wafer having a diameter as typically used in semiconductor facilities. For instance, in modem semiconductor facilities, the diameter of the substrate 101 may range from 200-300 mm. A silicon dioxide layer 102 is formed on the substrate 101, wherein, for the sake of simplicity, a thickness of the silicon dioxide layer 102 is illustrated in an exaggerated manner, whereas the substrate 101 is depicted as significantly reduced in thickness compared to the actual dimensions. For example, in advanced semiconductor devices, the thickness of the silicon dioxide layer 102 may range from approximately 1-5 nm, whereas the substrate 101 may have a typical thickness in the range of approximately several hundred micrometers. Moreover, the silicon dioxide layer 102 is to represent an insulating layer that may subsequently be patterned into gate insulation layers of transistor elements, such as NMOS and PMOS transistors, which in turn are provided in a large number on a plurality of die areas arranged across the entire substrate 101.

The silicon dioxide layer 102 may be provided as a thermal oxide created by conventional oxide growth techniques, such as rapid thermal oxidation or any other conventional furnace processes. As pointed out above, the silicon dioxide layer 102 having a thickness of approximately 1-5 mn may not sufficiently comply with device requirements in view of leakage current and capacitive coupling. Therefore, the incorporation of high amounts of nitrogen into the silicon dioxide layer 102 may be necessary so as to increase the dielectric constant thereof as well as enhance the resistance against charge carrier migration through the layer 102. Furthermore, a high nitrogen content may also be required as a diffusion barrier for boron atoms, which may penetrate the silicon dioxide layer 102 and the underlying substrate 101 during and after the implantation of the boron into polysilicon gate electrodes. The gate electrodes are usually formed on the silicon dioxide layer 102 when used as a gate insulation layer for a respective transistor structure.

FIG. 1b schematically shows the semiconductor device 100 when exposed to a nitrous plasma ambient, i.e., a nitrogen containing plasma, that may be established by known deposition tools including appropriate plasma equipment. Due to tool non-uniformities of presently available deposition tools and owing to the large diameter of the substrate 101, the nitrous plasma ambient may exhibit systematic variations across the substrate surface, which may lead to a non-uniform rate of nitrogen incorporation. For example, non-planar electrode arrangements in a plasma excitation means may lead to a varying nitrogen ion concentration across the substrate 101, thereby creating a non-uniform nitrogen concentration within the silicon dioxide layer 102.

FIG. 1c schematically shows a typical example of a non-uniform nitrogen concentration as is obtained by a conventional nitridation process. In this example, the nitrogen concentration at a center region 104 is significantly higher than at peripheral regions 105. A typical concentration difference between the center region 104 and the peripheral region 105 may be on the order of 1-5%. A corresponding variation of the nitrogen concentration may, however, not be tolerable in producing high-end CMOS devices, since especially the threshold voltage of a PMOS transistor is extremely sensitive to the amount of nitrogen contained in a respective gate insulation layer. Consequently, significant threshold variations across the substrate area may occur, wherein a reduced nitrogen concentration yields a relatively low threshold voltage of corresponding PMOS transistors, whereas a high nitrogen concentration increases the corresponding threshold voltage. Thus, integrated circuits formed at different areas of the substrate 101 may significantly differ in their electrical characteristics and therefore at least some of the integrated circuits may fail to comply with the specifications established for the integrated circuits.

FIG. 1d is a graph illustrating the cumulative probability of the occurrence of a specified threshold voltage of a PMOS transistor. The vertical axis represents the probability, i.e., the number of PMOS devices exhibiting a specified threshold voltage. The horizontal axis represents the threshold voltage of a PMOS transistor. As is evident from FIG. 1d, a relatively wide range Vᵢ, V_{f} of the threshold voltages with a significant probability in the range of Pᵢ, P_{f} is obtained. Although the relationship between the probability, i.e., the number of devices having a specified threshold voltage and the corresponding threshold voltage, is represented by a substantially linear curve, it nevertheless clearly demonstrates the great variation in threshold voltages occurring in PMOS transistors that are formed with a gate insulation layer having a nitrogen concentration variation as shown, for example, in the silicon dioxide layer 102. Although the distribution of the final nitrogen concentration across the substrate 101 may differ from that shown in FIG. 1c, for example, the pattern of distribution variations may significantly depend on the deposition tool used, the curve shown in FIG. 1d may nevertheless be representative for a plurality of possible distribution non-uniformities.

Consequently, due to the problems identified above, there exists an urgent need for integration schemes accounting for non-uniformities of a nitrogen concentration within a thin insulating layer.

### SUMMARY OF THE INVENTION

The present invention is based on the finding that one or more effects of interest of nitrogen concentration variations within an insulating material may be compensated for by modifying a thickness of the insulating layer in conformity with the nitrogen concentration within the insulating layer. In this way, a reduced nitrogen concentration in a specific area may be accounted for by increasing the thickness of the insulating layer and vice versa. If the insulating layer is to be used as a gate insulation layer for PMOS transistors, corresponding variations of the threshold voltages may significantly be reduced.

According to one illustrative embodiment of the present invention, a method of forming an insulation layer comprises forming a dielectric layer with an initial thickness on an oxidizable substrate and introducing nitrogen into the dielectric layer. Moreover, the initial thickness of the dielectric layer is locally increased according to a local nitrogen concentration.

### BRIEF DESCRIPTION OF THE DRAWINGS

The invention may be understood by reference to the following description taken in conjunction with the accompanying drawings, in which like reference numerals identify like elements, and in which:

FIGS. 1a-1c schematically show the formation of a thin oxide layer as is used for gate insulation layers of transistor structures during various manufacturing stages according to a conventional process flow;

FIG. 1d depicts a graph illustrating the variation of threshold voltages of PMOS transistors including a gate insulation layer as fabricated in accordance with the above conventional process flow;

FIGS. 2a-2d schematically show the formation of a thin insulating layer according to illustrative embodiments of the present invention; and

FIG. 2e depicts a graph illustrating the variation of threshold voltages of PMOS transistors including a gate insulation layer as fabricated in accordance with the inventive process flow.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Although the various regions and structures of a semiconductor device are depicted in the drawings as having very precise, sharp configurations and profiles, those skilled in the art recognize that, in reality, these regions and structures are not as precise as indicated in the drawings. Additionally, the relative sizes of the various features and doped regions depicted in the drawings may be exaggerated or reduced as compared to the size of those features or regions on fabricated devices. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the tern or phrase.

In the following illustrative embodiments, reference will be made to the formation of an insulation layer that is advantageous as a gate insulation layer of field effect transistors, especially for PMOS transistors, since a high degree of uniformity of the gate insulation layer may be obtained regarding the threshold voltage of the PMOS transistors even when fabricated at very different locations of a substrate. The application of the principles of the present invention to extremely scaled gate insulation layers exhibiting reduced leakage and enhanced permittivity should, however, not be considered as limiting. Rather, the formation of very thin dielectric layers are or may become relevant in a plurality of applications, such as memory devices, the dielectric of capacitors, as are frequently used as decoupling capacitors in CMOS devices, in opto-electronic microstructures, in micromechanical structures in the field of nanotechnology, and the like.

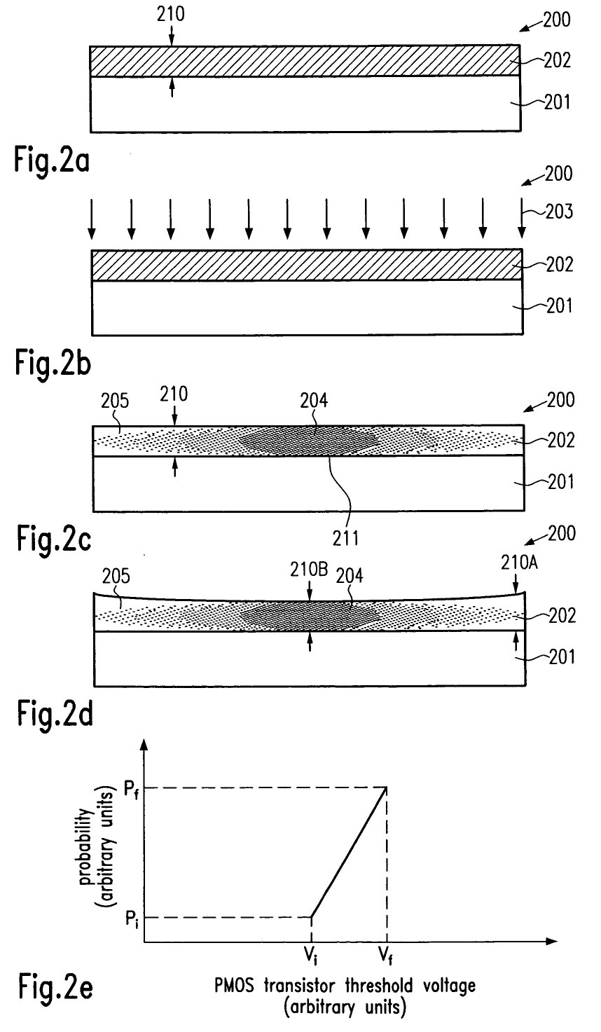

Further illustrative embodiments of the present invention will now be described in more detail with reference to FIGS. 2a-2d. FIG. 2a schematically shows a cross-sectional view of a semiconductor device 200 at an early manufacturing stage. The semiconductor device 200 comprises a substrate 201, which may be any appropriate substrate for forming microstructure elements and especially integrated circuits, wherein the substrate 201 includes an oxidizable semiconductor layer for the fabrication of circuit elements, such as field effect transistors and the like. In one particular embodiment, the substrate 201 is configured to allow the formation of circuit elements according to an advanced CMOS technology based on silicon. That is, the substrate 201 may represent a silicon substrate or a silicon-on-insulator (SOI) substrate having formed thereon a crystalline silicon layer. An insulating layer 202 having an initial thickness 210 is formed on the substrate 201. The insulating layer 202 may comprise any appropriate dielectric material, such as an oxide, that enables the insulating layer 202 to provide the required physical characteristics of microstructural elements or circuit elements to be formed on the insulating layer 202. In one particular embodiment, the insulating layer 202 is substantially comprised of silicon dioxide. The initial thickness 210 is deliberately selected so as to be less than a desired design thickness required for the formation of any elements of interest. In particular, in some embodiments, the insulating layer 202 is employed for the formation of gate insulation layers of PMOS transistors, wherein, in highly sophisticated integrated circuits, the corresponding thickness of the gate insulation layer has to be scaled down in conformity with the critical dimensions of the respective transistor elements. Therefore, in some embodiments, the insulating layer 202 is substantially comprised of silicon dioxide with the initial thickness 210 in the range of approximately 0.5-5 nm. It should be emphasized that the initial thickness 210 varies only slightly across the entire surface of the substrate 201 due to the high precision standards offered by advanced techniques for forming the insulating layer 202.

In a typical process flow for forming the semiconductor device 200, the insulating layer 202 may be formed by well-established thermal growth techniques, such as a rapid thermal oxidation. Any other appropriate and well-established oxidation methods, such as a standard furnace process, may also be used. In other embodiments, the insulating layer 202, when, for example, being comprised of silicon dioxide, may be formed by advanced deposition methods, such as plasma enhanced chemical vapor deposition, atomic layer deposition, and the like, thereby using appropriate precursor gases such as silane, TEOS, and the like. Respective process techniques are well established in the art and thus a description thereof is omitted. In still other embodiments, the insulating layer 202 may be provided by a chemical reaction, for example during and/or after the cleaning of the substrate 201 by appropriate reagents, which then may form an oxide layer. Irrespective of the technique used for forming the insulating layer 202, at least one process parameter, such as process time, may be controlled to obtain the initial thickness 210 within tightly set tolerances across the entire substrate 201. As previously noted, in advanced semiconductor facilities, a typical diameter of the substrate 201 is in the range of 200-300 mm. However, the present invention is readily applicable to substrates having a diameter less than specified above or to substrates of future device generations, which may have even greater diameters.

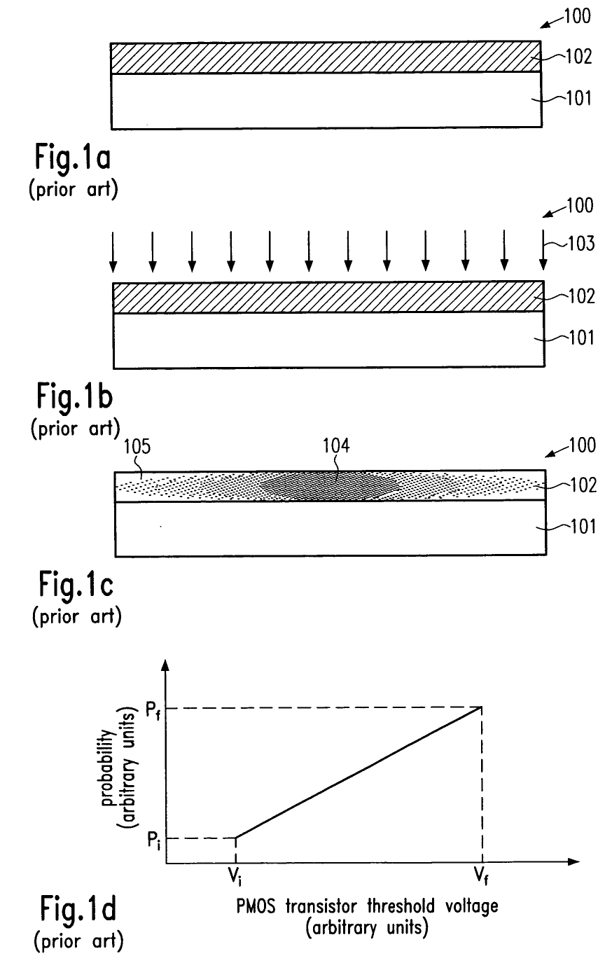

FIG. 2b schematically shows the semiconductor device 200 when exposed to a nitrous plasma ambient 203. As previously explained with reference to FIG. 1b, the nitrous plasma ambient 203 is selected so as to provide the required nitrogen concentration within the insulating layer 202, wherein typically process parameters, such as pressure of the ambient 203, any bias voltage applied to the substrate 201 for increasing the directionality of the plasma particles within the ambient 203, and the like, may be adjusted to control the process of introducing nitrogen into the layer 202. During the exposure to the ambient 203, local variations of one or more of the process parameters may occur and lead to a local variation of the nitrogen density and, thus, of the transfer rate of nitrogen into the insulating layer 202. Moreover, subtle changes of the corresponding plasma tool or minor non-uniformities of certain components of the tool, such as a non-uniformity of plasma exciting electrodes, bias electrodes and the like, may lead to process non-uniformities resulting in a systematic variation of the nitrogen concentration within the insulating layer 202 across the substrate 201, especially when large diameter substrates are employed. Since nitridation process schemes are well-known in the art, a detailed description thereof is omitted.

FIG. 2c schematically shows the semiconductor device 200 after the incorporation of nitrogen after or during the exposure to the nitrous plasma ambient 203. Similar to the example shown in FIG. 1c, in this case, a non-uniformity also may have occurred, leading to an increased nitrogen concentration, for example, at a central region 204, and to a reduced nitrogen concentration at peripheral regions 205. It should be emphasized, however, that any process non-uniformities and/or tool non-uniformities during the creation of the nitrous plasma ambient 203 may entail other concentration variations shown in FIG. 2c. For instance, the nitrogen concentration may increase and decrease several times across the diameter of the substrate 201, thereby generating a plurality of local maxima and minima of the nitrogen concentration. Irrespective of the precise pattern of the variations of the nitrogen concentration, at least some regions of the substrate 201, such as the regions 204 and 205, may exhibit a different nitrogen content that may entail a significant difference in at least one characteristic of the insulating layer 202, especially if a threshold voltage of a PMOS transistor is considered, in which the insulating layer 202 is used as a gate insulation layer.

For this reason, according to the present invention, the initial thickness 210 is modified in accordance with a variation of the nitrogen contents within the layer 202. In one embodiment, the substrate 201 is subjected to a heat treatment in an oxidizing ambient to further increase the initial thickness 210 to a finally required thickness as dictated by the further purpose of the insulating layer 202. During the further oxidation of the insulating layer 202, oxygen will diffuse faster in regions with relatively low nitrogen concentration, such as the regions 205, whereas the oxygen flux to an interface 211 between the insulating layer 202 and the substrate 201 is reduced in regions with high nitrogen concentration, such as the central region 204. Due to the differing diffusion rates of oxygen to the interface 211, a locally differing oxidation rate and thus a locally varying thickness of the insulating layer 202 is created. Therefore, the final thickness of the insulating layer 202 at the peripheral regions 205, having the low nitrogen concentration, is more intensively increased than a thickness at the central region 204 having the high nitrogen concentration, wherein the difference in thickness increase in the regions 204 and 205 is substantially determined by the difference in the nitrogen concentration. Hence, the thickness difference is created in a substantially self-adjusted manner.

FIG. 2d schematically shows the semiconductor device 200 with the insulating layer 202 having a locally varying thickness. As pointed out above, a thickness 210a at the peripheral region 205 is greater than a corresponding thickness 210b at the central region 204. Moreover, the thickness 210b is greater than the initial thickness 210, wherein a ratio of the initial thickness 210 and the final thickness, for example, at the central region 204, is controlled in conformity with design requirements for the insulating layer 202. For example, a desired equivalent oxide thickness, that is the physical thickness of a silicon dioxide layer having a specified permittivity, may be selected and a required nitrogen concentration for a insulating layer actually having a greater physical thickness may then be determined so as to achieve the same permittivity. Next, for a maximum tolerable process non-uniformity of the nitrous plasma ambient 203, a corresponding required thickness increase for a minimum nitrogen concentration to compensate for the lack of nitrogen may be determined, for example by calculation and/or experiment. Then, the initial thickness 210 may be selected in such a manner that the final thickness 210b at areas having the nominal nitrogen concentration substantially corresponds to the desired design thickness. In other areas, such as the peripheral regions 205, the thickness is then increased so as to compensate for the lack of nitrogen. Depending on the capability of presently available and future plasma tools for establishing the nitrous plasma ambient 203, the degree of compensation required for providing a substantially uniform characteristic of the insulating layer 202 may be taken into account by correspondingly adjusting the above-described ratio.

For example, a sophisticated transistor element may require an equivalent oxide thickness of 0.8 mn, which would, however, lead to intolerable leakage currents as well as device degradation, as previously pointed out. A nitrogen rich silicon dioxide layer having a physical thickness of approximately 1.3 nm may therefore be selected as the target thickness of the insulating layer 202, wherein the nitrogen concentration is selected to substantially achieve the permittivity of the target equivalent oxide thickness. For a given process variation of approximately 1-5% in introducing nitrogen into the insulating layer 202, the initial thickness 210 may be selected to be approximately 1.0 nm prior to exposure to the nitrous ambient 203. Subsequently, an oxidizing heat treatment may be carried out so as to substantially obtain the target thickness of approximately 1.2 nm at portions having a maximum nitrogen concentration. Due to the increased oxygen diffusion at lower nitrogen concentrations, a thickness at the respective portions 205, such as the thickness 210a, is then correspondingly increased depending on the difference of nitrogen compared to the nominal nitrogen concentration. Thus, the increase in thickness also increases a threshold voltage of a respective transistor structure due to a decreased permittivity in the regions 205, thereby significantly reducing a sensitivity of PMOS transistors to nitrogen variations.

In some embodiments, the nitrogen non-uniformity obtained during the exposure to the nitrous plasma ambient 203 may be determined on the basis of test substrates or based on measurements obtained from product substrates so as to correspondingly adjust process parameters of the subsequent oxidizing heat treatment to obtain the desired target thickness. In other embodiments, the actual thickness, for example at the central region 204, may be controlled during the oxidizing heat treatment so as to discontinue the treatment after a specified thickness is achieved. By processing one or more test substrates, a degree of compensation required to achieve a variation of the insulating layer 202 with respect to a specific characteristic may be determined in advance in order to obtain reliable process parameters, such as a thickness of the initial thickness 210, conditions in establishing the nitrous plasma ambient 203, and the subsequent oxidizing heat treatment.

FIG. 2e schematically shows a graph representing a cumulative probability varying between a first value Pᵢ and a second value P_{f} versus the range of tolerable threshold voltages in a range Vᵢ and V_{f}. Compared to the corresponding graph shown in FIG. 1d, the variation of the threshold voltages is significantly reduced due to the thickness variation in conformity with the varying nitrogen concentrations in the layer 202. As a consequence of the reduced variation of the threshold voltages of PMOS transistors across the entire substrate 201, design tolerances may be set more tightly, without requiring increased cost and effort on the tool side. Similarly, for a continuously improving precision of future tools for establishing the nitrous plasma ambient 203, an even more improved uniformity of the threshold voltage of PMOS transistors may then be obtained in accordance with the present invention, thereby enhancing production yield.

In the above-described embodiments, the heat treating for a further oxidation of the substrate 201 to locally increase the thickness of the insulating layer 202 has been described as a separate process step. In other embodiments, the thermal oxidation of the insulating layer 202 may be carried out in the same tool in which the nitrous plasma ambient 203 is established. For instance, an oxidizing ambient may be established after discontinuing a nitrogen supply to the ambient 203 or after deactivating a corresponding plasma generating means or after reducing power transfer thereto. In a further embodiment, oxygen may be introduced into the nitrous plasma ambient 203 during at least a part of a time interval while exposing the substrate 201 to the nitrous plasma ambient 203. For instance, oxygen may be introduced into the ambient 203 so as to simultaneously oxidize the substrate 201 and thereby increase the thickness of the insulating layer 202, wherein a growth rate is substantially determined by the nitrogen incorporation rate as defined by any non-uniformities of the ambient 203. Preferably, the oxygen is introduced at an advanced stage of the process for introducing the nitrogen so that the tool and ambient dependent nitrogen variation has already been established within the layer 202. The above “in-situ” embodiments, in which nitridation and oxidation occurs at least partially at the same time may, however, be considered appropriate only when an oxygen density above the substrate 201 is significantly more uniformly provided than the ionized nitrogen in the ambient 203. In other embodiments, oxygen may be supplied at a final phase of the nitrogen introduction, wherein supply of nitrogen is finally completely discontinued so as to increase the initial thickness 210 to the specified target thickness.

As a result, the present invention provides a technique for forming extremely thin insulation layers requiring the incorporation of specified amounts of nitrogen, wherein the effect of nitrogen variations across the substrate surface may be reduced in that during and/or after the nitrogen incorporation an oxidation process is performed. The nitrogen variations lead to a nitrogen concentration dependent oxidation rate and, hence, a nitrogen concentration dependent thickness variation of the insulating layer. In particular, the threshold variations of transistors including the thin insulating layer as a gate insulation layer may effectively be reduced.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method of forming an insulating layer, the method comprising:
forming a dielectric layer with an initial thickness on an oxidizable substrate;
introducing nitrogen into said dielectric layer; and
locally increasing said initial thickness of said dielectric layer according to a local nitrogen concentration.

2. The method of claim 1, wherein said initial thickness is locally increased by oxidizing said substrate.

3. The method of claim 1, wherein said dielectric oxide layer comprises silicon dioxide and the initial thickness is in the range of approximately 0.5-5 nm.

4. The method of claim 1, further comprising determining a ratio of said initial thickness and a maximum local increase to control a specific characteristic of said insulating layer.

5. The method of claim 4, wherein said ratio is determined as a target value in advance.

6. The method of claim 4, wherein said ratio is achieved by controlling at least one of said initial thickness, a process parameter while locally increasing said initial thickness, and a process parameter while introducing said nitrogen.

7. The method of claim 1, wherein said dielectric layer is formed by at least one of thermal growth, rapid thermal oxidation, chemical vapor deposition, atomic layer deposition and chemical reaction.

8. The method of claim 1, further comprising patterning said insulating layer as a plurality of gate insulation layers for PMOS transistors at different locations on said substrate.

9. The method of claim 1, wherein said nitrogen is introduced into said insulating layer by exposing said substrate to a nitrous plasma.

10. A method, comprising:
forming a silicon dioxide layer as a base layer for a gate dielectric with an initial thickness on a first area and a second area of a silicon containing semiconductor layer provided on a substrate;
introducing nitrogen into said silicon dioxide layer; and
increasing said initial thickness in said first and second areas on the basis of a nitrogen concentration contained therein and a desired characteristic of said gate dielectric.

11. The method of claim 10, wherein increasing said initial thickness includes oxidizing said substrate.

12. The method of claim 11, wherein oxidizing said substrate is performed after introducing nitrogen into said silicon dioxide layer.

13. The method of claim 11, wherein oxidizing said substrate is performed at least partially simultaneously with introducing nitrogen into said silicon dioxide layer.

14. The method of claim 10, further comprising determining a ratio of said initial thickness and a maximum thickness increase in one of said first and second areas to control a specific characteristic of said gate dielectric.

15. The method of claim 14, wherein said ratio is determined as a target value in advance.

16. The method of claim 15, wherein said ratio is achieved by controlling at least one of said initial thickness, a process parameter while locally increasing said initial thickness, and a process parameter while introducing said nitrogen.

17. The method of claim 10, wherein said silicon dioxide layer is formed by at least one of thermal growth, rapid thermal oxidation, chemical vapor deposition, atomic layer deposition and chemical reaction.

18. The method of claim 10, further comprising patterning said gate dielectric as a plurality of gate insulation layers for PMOS transistors at different locations on said substrate.

19. The method of claim 10, wherein said nitrogen is introduced into the base layer by exposing said substrate to a nitrous plasma.
